(19) United States
(12) Patent Application Publication
(10) Pub. No.: US 2005/0266694 A1
(43) Pub. Date: Dec. 1, 2005

(54) Controlling bubble formation during etching

(76) Inventors: Justin K. Brask, Portland, OR (US); Paul D. Sears, Beaverton, OR (US); Jack Kavalieros, Portland, OR (US); Mark L. Doczy, Beaverton, OR (US); Matthew V. Metz, Hillsboro, OR (US); Suman Datta, Beaverton, OR (US); Uday Shah, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 10/854,975

(22) Filed: May 27, 2004

(51) Int. Cl. H01L 21/461

(52) U.S. Cl. 438/748; 438/753

(57) ABSTRACT

A wafer may be rotated while etching to displace bubbles that may form, for example, from a reaction between silicon and water. As a result, a hydrophobic layer, which would otherwise be created by the bubbles, cannot form, resulting in a more uniform etch rate in some embodiments.

### BACKGROUND

The present invention relates to methods for making semiconductor devices, and, in particular, etching silicon in such processes.

In many semiconductor processing applications, it is necessary to etch silicon including polysilicon. Bubble formation during silicon etching may block the continued progress of the etching into the silicon. One application for silicon etching is in connection with forming metal gate electrodes.

MOS field-effect transistors with very thin gate dielectrics made from silicon dioxide may experience unacceptable gate leakage currents. Forming the gate dielectric from certain high-dielectric constant (k) dielectric materials, instead of silicon dioxide, can reduce gate leakage. High-k dielectric materials are materials with a dielectric constant greater than 10. Because, however, such a dielectric may not be compatible with polysilicon, it may be desirable to use metal gate electrodes in devices that include high-k gate dielectrics.

When making a complementary metal oxide semiconductor (CMOS) device that includes metal gate electrodes, a replacement gate process may be used to form gate electrodes from different metals. In that process, a first polysilicon layer, bracketed by a pair of spacers, is removed to create a trench between the spacers. The trench is filled with a first metal. A second polysilicon layer is then removed, and replaced with a second metal that differs from the first metal. Because this process requires multiple etch, deposition, and polish steps, high volume manufacturers of semiconductor devices may be reluctant to use it.

Rather than apply a replacement gate process to form a metal gate electrode on a high-k gate dielectric layer, a subtractive approach may be used. In such a process, a metal gate electrode is formed on a high-k gate dielectric layer by depositing a metal layer on the dielectric layer, masking the metal layer, and then removing the uncovered part of the metal layer and the underlying portion of the dielectric layer. Unfortunately, the exposed sidewalls of the resulting high-k gate dielectric layer render that layer susceptible to lateral oxidation, which may adversely affect its physical and electrical properties.

Accordingly, there is a need for better ways to etch silicon containing layers.

### BRIEF DESCRIPTION OF THE DRAWINGS

FIGS. 1A-1G represent cross-sections of structures that may be formed when carrying out an embodiment of the method of the present invention.

### DETAILED DESCRIPTION

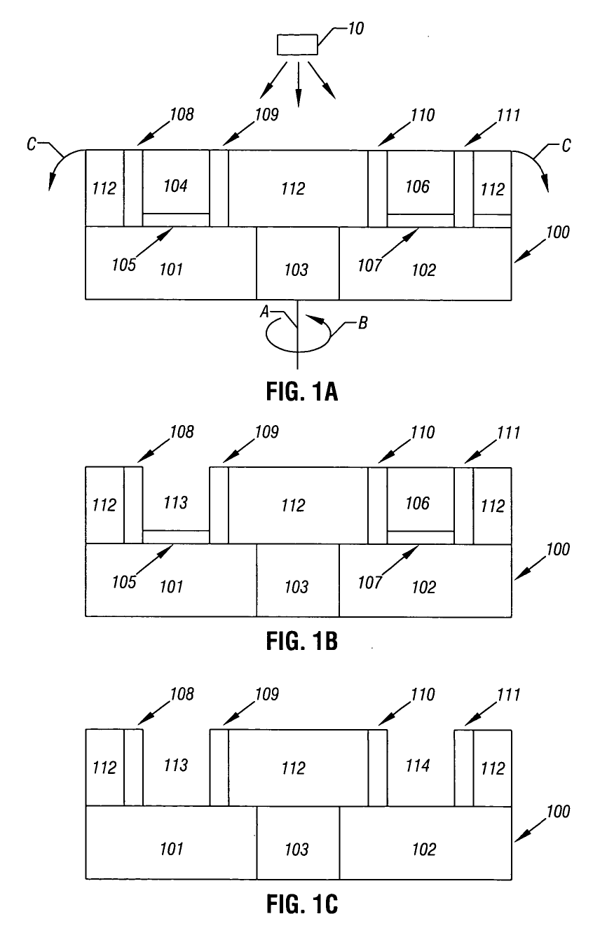

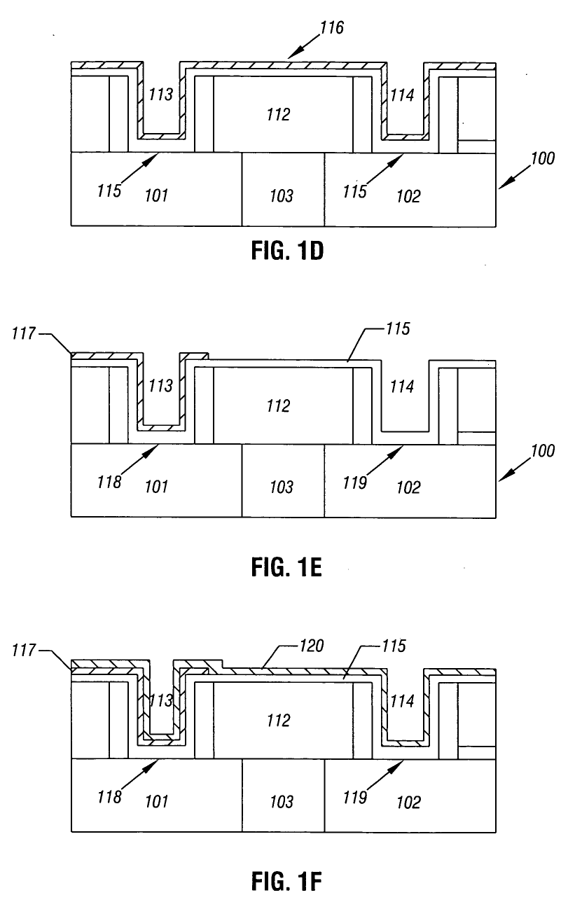

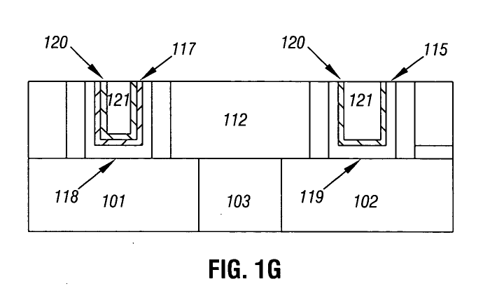

FIGS. 1A-1G illustrate structures that may be formed, when carrying out an embodiment of the method of the present invention. A metal gate replacement process is described herein. However, the present invention is not limited to use in metal gate replacement processes. Instead, it may be applied to various etching applications.

FIG. 1A represents an intermediate structure that may be formed when making a complementary metal oxide semiconductor (CMOS) device. That structure includes first part 101 and second part 102 of substrate 100. Isolation region 103 separates first part 101 from second part 102. First polysilicon layer 104 is formed on dielectric layer 105, and second polysilicon layer 106 is formed on dielectric layer 107. First polysilicon layer 104 is bracketed by a pair of sidewall spacers 108, 109, and second polysilicon layer 106 is bracketed by a pair of sidewall spacers 110, 111. Dielectric 112 lies next to the sidewall spacers.

Substrate 100 may comprise a bulk silicon or silicon-on-insulator substructure. Alternatively, substrate 100 may comprise other materials—which may or may not be combined with silicon—such as: germanium, indium antimonide, lead telluride, indium arsenide, indium phosphide, gallium arsenide, or gallium antimonide. Although a few examples of materials from which substrate 100 may be formed are described here, any material that may serve as a foundation upon which a semiconductor device may be built falls within the spirit and scope of the present invention.

Isolation region 103 may comprise silicon dioxide, or other materials that may separate the transistor's active regions. Dielectric layers 105, 107 may each comprise silicon dioxide, or other materials that may insulate the substrate from other substances. First and second polysilicon layers 104, 106 preferably are each between about 100 and about 2,000 Angstroms thick, and more preferably between about 500 and about 1,600 Angstroms thick. Those layers each may be undoped or doped with similar substances. Alternatively, one layer may be doped, while the other is not doped, or one layer may be doped n-type (e.g., with arsenic, phosphorus or another n-type material), while the other is doped p-type (e.g., with boron or another p-type material). Spacers 108, 109, 110, 111 preferably comprise silicon nitride, while dielectric 112 may comprise silicon dioxide, or a low-k material. Dielectric 112 may be doped with phosphorus, boron, or other elements, and may be formed using a high density plasma deposition process.

Conventional process steps, materials, and equipment may be used to generate the FIG. 1a structure, as will be apparent to those skilled in the art. As shown, dielectric 112 may be polished back, e.g., via a conventional chemical mechanical polishing (“CMP”) operation, to expose first and second polysilicon layers 104, 106. Although not shown, the FIG. 1a structure may include many other features (e.g., a silicon nitride etch stop layer, source and drain regions, and one or more buffer layers) that may be formed using conventional processes.

When source and drain regions are formed using conventional ion implantation and anneal processes, it may be desirable to form a hard mask on polysilicon layers 104, 106—and an etch stop layer on the hard mask—to protect layers 104, 106 when the source and drain regions are covered with a silicide. The hard mask may comprise silicon nitride, and the etch stop layer may comprise a material that will be removed at a substantially slower rate than silicon nitride will be removed when an appropriate etch process is applied. Such an etch stop layer may, for example, be made from silicon, an oxide (e.g., silicon dioxide or hafnium dioxide), or a carbide (e.g., silicon carbide).

Such an etch stop layer and silicon nitride hard mask may be polished from the surface of layers 104, 106, when dielectric layer 112 is polished—as those layers will have served their purpose by that stage in the process. FIG. 1a represents a structure in which any hard mask or etch stop layer, which may have been previously formed on layers 104, 106, has already been removed from the surface of those layers. When ion implantation processes are used to form the source and drain regions, layers 104, 106 may be doped at the same time the source and drain regions are implanted. In such a process, first polysilicon layer 104 may be doped n-type, while second polysilicon layer 106 is doped p-type—or vice versa.

After forming the FIG. 1a structure, first and second polysilicon layers 104, 106 are removed. In a preferred embodiment, those layers are removed by applying a wet etch process, or processes. Such a wet etch process may comprise exposing layers 104, 106 to an aqueous solution that comprises a source of hydroxide for a sufficient time at a sufficient temperature to remove substantially all of those layers. That source of hydroxide may comprise between about 2 and about 30 percent ammonium hydroxide or a tetraalkyl ammonium hydroxide, e.g., tetramethyl ammonium hydroxide (“TMAH”), by volume in deionized water.

An n-type polysilicon layer 104 may be selectively removed (to achieve the FIG. 1B structure) by exposing it to a flowing etching solution, which is maintained at a temperature between about 15° C. and about 90° C. (and preferably below about 40° C.), that comprises between about 2 and about 30 percent ammonium hydroxide by volume in deionized water. The solution may be dispensed from an axially located spray nozzle 10 in one embodiment.

During the etching step, hydrogen gas develops as a product of the reaction between water and silicon. The hydrogen gas build up may form a hydrophobic surface that blocks the penetration of the etchant into the polysilicon being etched.

The hydrogen gas build up may be controlled using centrifugal force, for example, by rotating the substrate 100 as indicated by the arrows B about the axis A. In one embodiment, a wafer may be rotated from about 500 to 700 rpm, causing the hydrogen gas bubbles to be dislodged, without impacting delicate structures formed on the rotated wafer. Etching solution may be displaced via centrifugal force from the wafer as indicated by the arrow C.

As an alternative, an n-type polysilicon layer may be removed by exposing it for at least one minute to a flowing solution, which is maintained at a temperature between about 60° C. and about 90° C., that comprises between about 20 and about 30 percent TMAH by volume in deionized water with wafer spinning. Substantially all of such an n-type polysilicon layer that is about 1,350 Angstroms thick may be removed by exposing it at about 80° C. for about 2 minutes to a solution that comprises about 25 percent TMAH by volume in deionized water while rotating the wafers.

A p-type polysilicon layer may also be removed by exposing it to a solution that comprises between about 20 and about 30 percent TMAH by volume in deionized water for a sufficient time at a sufficient temperature (e.g., between about 60° C. and about 90° C.), while spinning the wafers. Those skilled in the art will recognize that the particular wet etch process, or processes, that should be used to remove first and second polysilicon layers 104, 106 will vary, depending upon whether none, one or both of those layers are doped, e.g., one layer is doped n-type and the other p-type.

For example, if layer 104 is doped n-type and layer 106 is doped p-type, it may be desirable to first apply an ammonium hydroxide based wet etch process to remove the n-type layer followed by applying a TMAH based wet etch process to remove the p-type layer. Alternatively, it may be desirable to simultaneously remove layers 104, 106 with an appropriate TMAH based wet etch process.

After removing first and second polysilicon layers 104, 106, dielectric layers 105, 107 are exposed. In this embodiment, layers 105, 107 are removed.

When dielectric layers 105, 107 comprise silicon dioxide, they may be removed using an etch process that is selective for silicon dioxide. Such an etch process may comprise exposing layers 105, 107 to a solution that includes about 1 percent HF in deionized water. The time layers 105, 107 are exposed should be limited, as the etch process for removing those layers may also remove part of dielectric layer 112. With that in mind, if a 1 percent HF based solution is used to remove layers 105, 107, the device preferably should be exposed to that solution for less than about 60 seconds, and more preferably for about 30 seconds or less. As shown in FIG. 1C, removal of dielectric layers 105, 107 leaves trenches 113, 114 within dielectric layer 112 positioned between sidewall spacers 108, 109, and sidewall spacers 110, 111 respectively.

After removing dielectric layers 105, 107, dielectric layer 115 (FIG. 1D) is formed on substrate 100. Preferably, dielectric layer 115 comprises a high-k gate dielectric layer. Some of the materials that may be used to make such a high-k gate dielectric layer include: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Particularly preferred are hafnium oxide, zirconium oxide, and aluminum oxide. Although a few examples of materials that may be used to form a high-k gate dielectric layer are described here, that layer may be made from other materials.

High-k gate dielectric layer 115 may be formed on substrate 100 using a conventional deposition method, e.g., a conventional chemical vapor deposition (“CVD”), low pressure CVD, or physical vapor deposition (“PVD”) process. Preferably, a conventional atomic layer CVD process is used. In such a process, a metal oxide precursor (e.g., a metal chloride) and steam may be fed at selected flow rates into a CVD reactor, which is then operated at a selected temperature and pressure to generate an atomically smooth interface between substrate 100 and high-k gate dielectric layer 115. The CVD reactor should be operated long enough to form a layer with the desired thickness. In most applications, high-k gate dielectric layer 115 should be less than about 60 Angstroms thick, and more preferably between about 5 Angstroms and about 40 Angstroms thick.

As shown in FIG. 1D, when an atomic layer CVD process is used to form high-k gate dielectric layer 115, that layer will form on the sides of trenches 113, 114 in addition to forming on the bottom of those trenches. If high-k gate dielectric layer 115 comprises an oxide, it may manifest oxygen vacancies at random surface sites and unacceptable impurity levels, depending upon the process used to make it. It may be desirable to remove impurities from layer 115, and to oxidize it to generate a layer with a nearly idealized metal: oxygen stoichiometry, after layer 115 is deposited.

To remove impurities from that layer and to increase that layer's oxygen content, a wet chemical treatment may be applied to high-k gate dielectric layer 115. Such a wet chemical treatment may comprise exposing high-k gate dielectric layer 115 to a solution that comprises hydrogen peroxide at a sufficient temperature for a sufficient time to remove impurities from high-k gate dielectric layer 115 and to increase the oxygen content of high-k gate dielectric layer 115. The appropriate time and temperature at which high-k gate dielectric layer 115 is exposed may depend upon the desired thickness and other properties for high-k gate dielectric layer 115.

When high-k gate dielectric layer 115 is exposed to a hydrogen peroxide based solution, an aqueous solution that contains between about 2% and about 30% hydrogen peroxide by volume may be used. That exposure step should take place at between about 15° C. and about 40° C. for at least about one minute. In a particularly preferred embodiment, high-k gate dielectric layer 115 is exposed to an aqueous solution that contains about 6.7% H₂O₂ by volume for about 10 minutes at a temperature of about 25° C. During that exposure step, it may be desirable to apply sonic energy at a frequency of between about 10 KHz and about 2,000 KHz, while dissipating at between about 1 and about 10 watts/cm². In a preferred embodiment, sonic energy may be applied at a frequency of about 1,000 KHz, while dissipating at about 5 watts/cm².

Although not shown in FIG. 1D, it may be desirable to form a capping layer, which is no more than about five monolayers thick, on high-k gate dielectric layer 115. Such a capping layer may be formed by sputtering one to five monolayers of silicon, or another material, onto the surface of high-k gate dielectric layer 115. The capping layer may then be oxidized, e.g., by using a plasma enhanced chemical vapor deposition process or a solution that contains an oxidizing agent, to form a capping dielectric oxide.

Although in some embodiments it may be desirable to form a capping layer on high-k gate dielectric layer 115, in the illustrated embodiment, metal layer 116 is formed directly on layer 115 to generate the FIG. 1C structure. Metal layer 116 may comprise any conductive material from which a metal gate electrode may be derived, and may be formed on high-k gate dielectric layer 115 using well known PVD or CVD processes. Examples of n-type materials that may be used to form metal layer 116 include: hafnium, zirconium, titanium, tantalum, aluminum, and metal carbides that include these elements, i.e., titanium carbide, zirconium carbide, tantalum carbide, hafnium carbide and aluminum carbide. Examples of p-type metals that may be used include: ruthenium, palladium, platinum, cobalt, nickel, and conductive metal oxides, e.g., ruthenium oxide. Although a few examples of materials that may be used to form metal layer 116 are described here, that layer may be made from many other materials.

Metal layer 116 should be thick enough to ensure that any material formed on it will not significantly impact its workfunction. Preferably, metal layer 116 is between about 25 Angstroms and about 300 Angstroms thick, and more preferably is between about 25 Angstroms and about 200 Angstroms thick. When metal layer 116 comprises an n-type material, layer 116 preferably has a workfunction that is between about 3.9 eV and about 4.2 eV. When metal layer 116 comprises a p-type material, layer 116 preferably has a workfunction that is between about 4.9 eV and about 5.2 eV.

After forming metal layer 116 on high-k gate dielectric layer 115, part of metal layer 116 is masked. The exposed part of metal layer 116 is then removed, followed by removing any masking material, to generate the structure of FIG. 1E. In that structure, first metal layer 117 is formed on first part 118 of high-k gate dielectric layer 115, such that first metal layer 117 covers first part 118 of high-k gate dielectric layer 115, but does not cover second part 119 of high-k gate dielectric layer 115. Although conventional techniques may be applied to mask part of metal layer 116, then to remove the exposed part of that layer, it may be desirable to use a spin on glass (“SOG”) material as the masking material, as described below.

In this embodiment, second metal layer 120 is then deposited on first metal layer 117 and exposed second part 119 of high-k gate dielectric layer 115—generating the structure illustrated by FIG. 1F. If first metal layer 117 comprises an n-type metal, e.g., one of the n-type metals identified above, then second metal layer 120 preferably comprises a p-type metal, e.g., one of the p-type metals identified above. Conversely, if first metal layer 117 comprises a p-type metal, then second metal layer 120 preferably comprises an n-type metal.

Second metal layer 120 may be formed on high-k gate dielectric layer 115 and first metal layer 117 using a conventional PVD or CVD process, preferably is between about 25 Angstroms and about 300 Angstroms thick, and more preferably is between about 25 Angstroms and about 200 Angstroms thick. If second metal layer 120 comprises an n-type material, layer 120 preferably has a workfunction that is between about 3.9 eV and about 4.2 eV. If second metal layer 120 comprises a p-type material, layer 120 preferably has a workfunction that is between about 4.9 eV and about 5.2 eV.

In this embodiment, after depositing second metal layer 120 on layers 117 and 115, the remainder of trenches 113, 114 is filled with a material that may be easily polished, e.g., tungsten, aluminum, titanium, or titanium nitride. Such a trench fill metal, e.g., metal 121 (FIG. 1G), may be deposited over the entire device using a conventional metal deposition process. That trench fill metal may then be polished back so that it fills only trenches 113, 114, as shown in 1f.

After removing trench fill metal 121, except where it fills trenches 113, 114, a capping dielectric layer (not shown) may be deposited onto the resulting structure using any conventional deposition process. Process steps for completing the device that follow the deposition of such a capping dielectric layer, e.g., forming the device's contacts, metal interconnect, and passivation layer, are well known to those skilled in the art and will not be described here.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
rotating a wafer during wet etching of that wafer.

2. The method of claim 1 including rotating the wafer while etching silicon.

3. The method of claim 1 including rotating the wafer while etching polysilicon.

4. The method of claim 1 including applying wet etchant to the wafer through a nozzle.

5. The method of claim 1 including rotating the wafer to dissipate bubbles formed by the etching process.

6. The method of claim 1 including rotating the wafer at a speed sufficient to dissipate bubbles formed on the wafer.

7. The method of claim 1 including rotating the wafer at at least 500 rpm.

8. The method of claim 1 including removing polysilicon by etching in ammonium hydroxide while rotating said wafer.

9. The method of claim 1 including rotating said wafer while etching polysilicon in a solution including NH₄OH.

10. The method of claim 1 including rotating the wafer while etching polysilicon gate material and replacing said etched away polysilicon gate material with a metal gate.

11. A method comprising:
forming a polysilicon gate material on a semiconductor structure; and
etching said polysilicon gate material in a wet solution while rotating said semiconductor structure.

12. The method of claim 11 including etching the polysilicon using tetramethyl ammonium hydroxide.

13. The method of claim 11 including etching polysilicon using NH₄OH.

14. The method of claim 11 including selectively etching n-type doped polysilicon versus p-type doped polysilicon.

15. The method of claim 11 including rotating the semiconductor structure while flowing etchant over said semiconductor structure.

16. The method of claim 15 including rotating said semiconductor structure at at least 500 rpm.

17. The method of claim 11 including rotating the wafer sufficiently fast to dissipate bubbles formed on said polysilicon.

18. A method comprising:
dissipating bubbles formed during etching by applying centrifugal force to an etched structure.

19. The method of claim 18 including rotating a semiconductor wafer being etched.

20. The method of claim 19 including flowing an etchant over said wafer while rotating said wafer.
